(19) United States
(12) Patent Application Publication
(10) Pub. No.: US 2015/0062788 A1
(43) Pub. Date: Mar. 5, 2015

(54) RACK-MOUNT SERVER ASSEMBLY WITH CABLE MANAGEMENT APPARATUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: Wan-Li NING, Shenzhen (CN); An-Gang LIANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/016,242

(22) Filed: Sep. 3, 2013

(30) Foreign Application Priority Data
Aug. 27, 2013 (CN) 2013103777347

(51) Int. Cl. H05K 7/14; H02G 3/34

(52) U.S. Cl. CPC H05K 7/14; H02G 3/34
USPC 361/679.02; 174/135

(57) ABSTRACT

A rack-mount server assembly includes a rack, a server module mounted in the rack, a switch mounted in the rack and above the server module, cables connected between the server module and the switch, and a cable management apparatus. The switch and the server module cooperatively bound a space. The cable management apparatus includes a frame mounted to the rack and covering the space, a sliding member slidably installed in the frame, and an air shield member mounted on an end of the sliding member. The frame defines a through hole aligning with the space for the cables extending through. The sliding member is slid to allow the air shield member to cover or uncover the space. The cables extend through the air shield member in response to the air shield member covering the space.

### BACKGROUND

1. Technical Field

The present disclosure relates to a rack-mount server assembly including a cable management apparatus.

2. Description of Related Art

A rack-mount server assembly includes a rack, a plurality of server modules received in the rack, and a switch generally mounted on a top of the rack. Many cables are connected between the server modules and the switch for transferring signals or providing power. However, connectors of the server modules and connectors of the switch are not located at the same side, thus, a space is needed between the switch and the server modules for the cables to extend through. However, the space may influence the heat dissipation effectiveness in the rack.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of a rack-mount server assembly, wherein the rack-mount server assembly includes a cable management apparatus.

FIG. 2 is an exploded, enlarged view of the cable management apparatus of FIG. 1.

FIG. 3 is similar to FIG. 2, but viewed from another perspective.

FIG. 4 is an assembled, isometric view of the cable management apparatus of FIG. 2.

FIG. 5 is an assembled, isometric view of FIG. 1, showing the cable management apparatus in use.

FIG. 6 is an enlarged view of the circled portion VI of FIG. 5.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

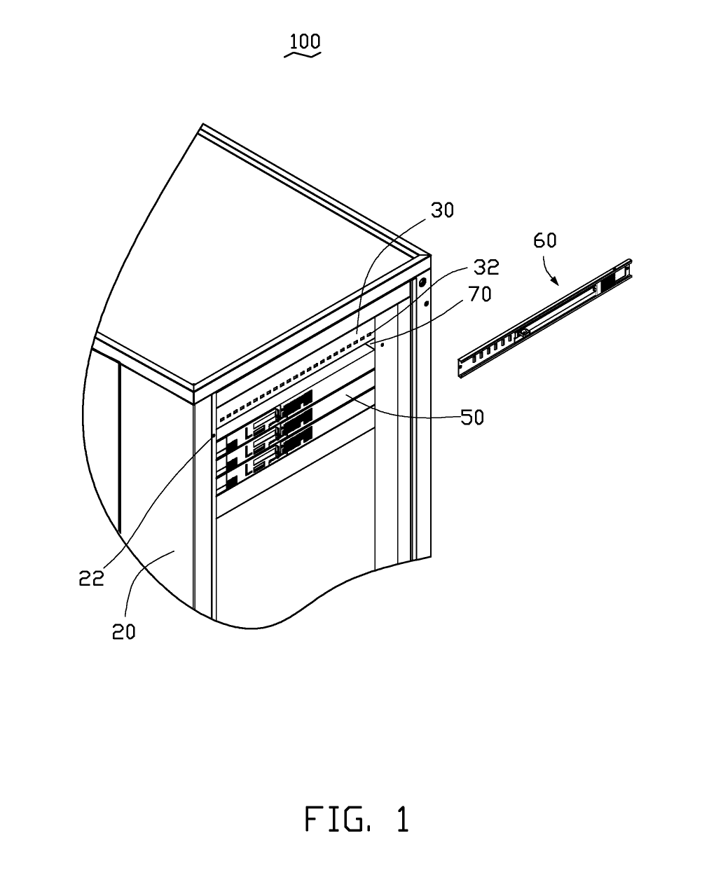

FIG. 1 shows an exemplary embodiment of a rack-mount server assembly 100. The rack-mount server assembly 100 includes a rack 20, a plurality of server modules 50 received in the rack 20, a switch 30 received in the rack 20 positioned above the server modules 50, and a cable management apparatus 60. The switch 30 includes a plurality of first connectors 32 positioned at a rear side of the switch 30. Each server module 50 includes a plurality of second connectors (not shown) located at a front side of the server module 50 opposite to the first connectors 32. A space 70 is defined between the switch 30 and the server module 50. The rack 20 defines two screw holes 22 adjacent to two opposite ends of the space 70.

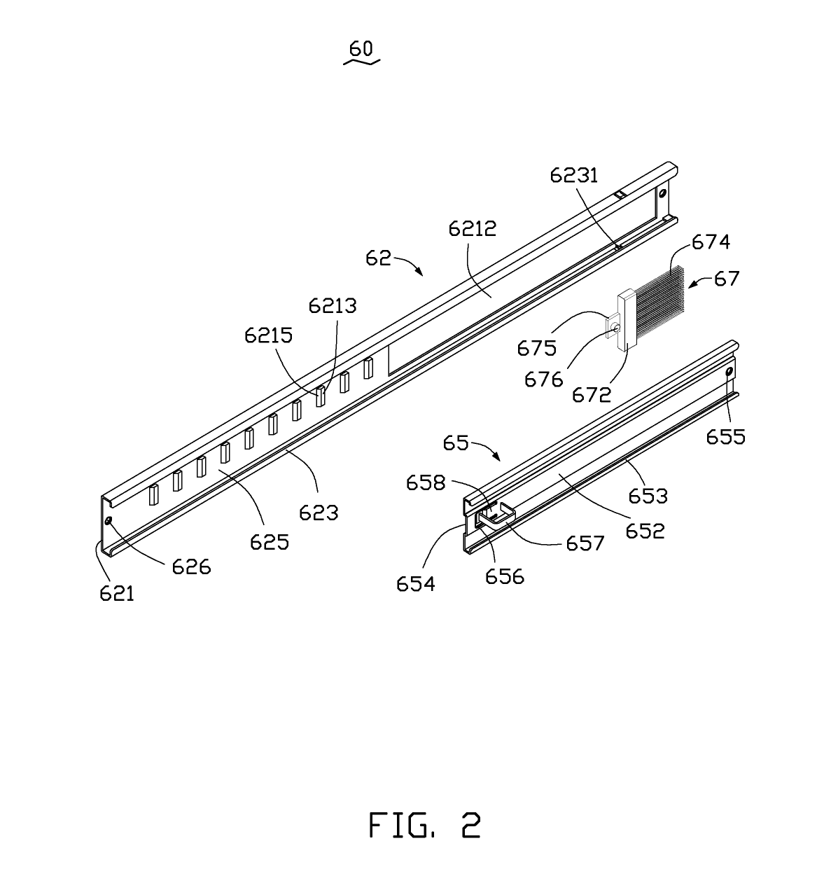

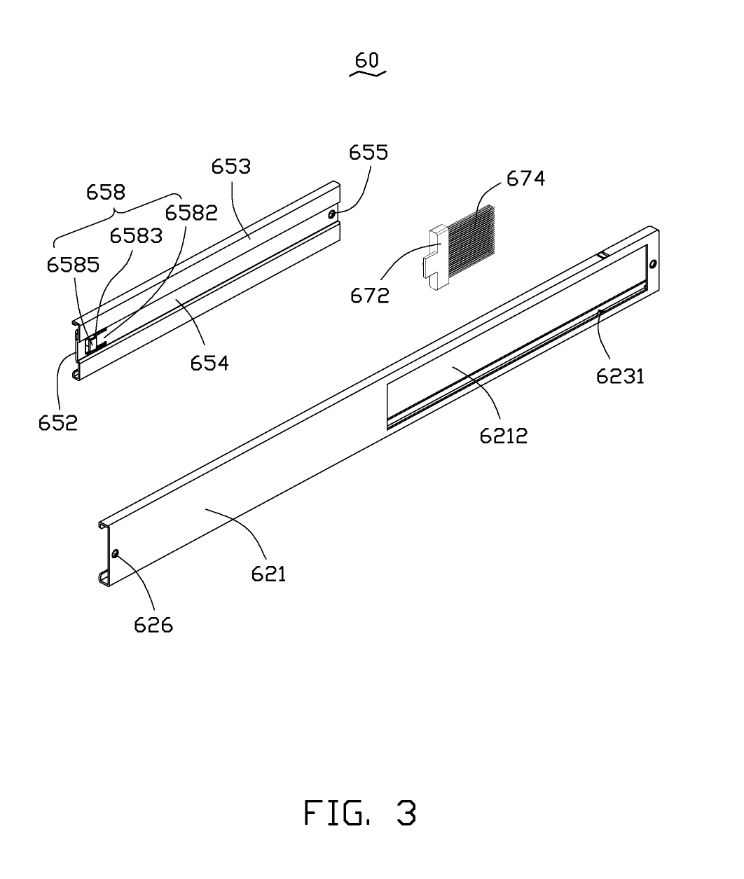

FIGS. 2 and 3 show the cable management apparatus 60 including a frame 62, a sliding member 65, and an air shield member 67.

The frame 62 includes a rectangular mounting plate 621, and two L-shaped flanges 623 firstly extending from two opposite sides of the mounting plate 621 toward the same direction and then extending toward each other. The mounting plate 621 and the flanges 623 cooperatively bound a receiving slot 625. First and second ends of the mounting plate 621 define two mounting holes 626. The first end of the mounting plate 621 defines a long through hole 6212 extending along a lengthwise direction of the mounting plate 621. A row of latching blocks 6213 protrudes from the second end of the mounting plate 621 toward the receiving slot 625. The latching blocks 6213 are arrayed along the lengthwise direction of the mounting plate 621. Each latching block 6213 defines a slanting guiding surface 6215 opposite to the through hole 6212. A stopping piece 6231 protrudes from each flange 623 toward the receiving slot 625, adjacent to the first end of the mounting plate 621.

The sliding member 65 includes a sliding bar 652 and two guiding bars 653 extending out from two opposite sides of the sliding bar 652. The sliding bar 652 is substantially U-shaped in cross section. An inner side of the sliding bar 652 facing the frame 62 defines a guiding slot 654 extending along a lengthwise direction of the sliding bar 653. A first end of the sliding bar 652 defines a latching hole 655. A second end of the sliding bar 652 defines a rectangular slot 656. A resilient tongue 658 extends into the slot 656 from an end wall bounding an end of the slot 656 adjacent to the latching hole 655. The tongue 658 includes a resilient extending portion 6582 extending into the slot 656 from the sliding bar 652, a guiding portion 6583 slantingly extending from a distal end of the extending portion 6582 away from the extending portion 6582, and a latching portion 6585 extending from a distal end of the guiding portion 6583 along the same direction with the extending portion 6582. A U-shaped operation portion 657 protrudes out from an outer surface of the tongue 658 opposite to the guiding portion 6583.

In the embodiment, the air shield member 67 is a brush. The air shield member 67 includes a handle 672 and a brush portion 674. A tab 675 protrudes out from a side of the handle 672 away from the brush portion 674. A pin 676 perpendicularly extends out from the tab 675.

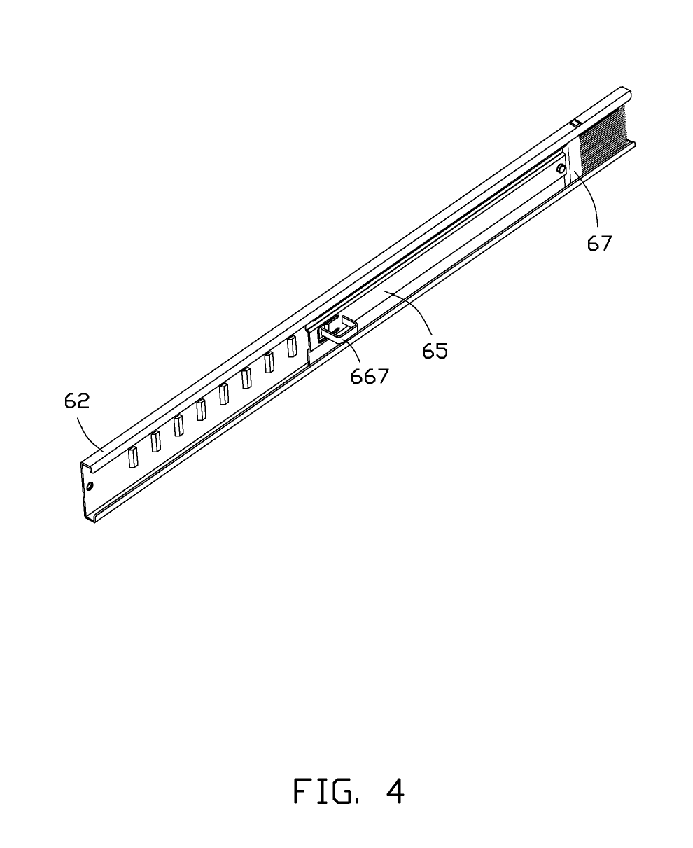

FIG. 4 shows that in assembly of the cable management apparatus 60, the air shield member 67 is placed to the first end of the sliding member 65, with the tab 675 received in the guiding slot 654 and the pin 676 latched in the latching hole 655. The air shield member 67 is inserted in the receiving slot 625 from the second end of the frame 62. The guiding bars 653 and two opposite ends of the handle 672 are slidably engaged with inner surfaces of the flanges 623. The latching blocks 6213 are received in the guiding slot 654 of the sliding member 65, and the tongue 658 aligns with the latching blocks 6213. The guiding portion 6583 is slidably abutted against the guiding surface 6215 of each latching block 6213, deforming the extending portion 6582, until the latching portion 6585 moves across the latching block 6213. The extending portion 6582 is restored to bias the latching portion 6585 to latch with the corresponding latching block 6213. A combination of the air shield member 67 and the sliding member 65 is slid in the receiving slot 625, until the handle 672 is stopped by the stopping pieces 6231. Therefore, the through hole 6212 of the frame 62 is covered through the sliding member 65 and the air shield member 67.

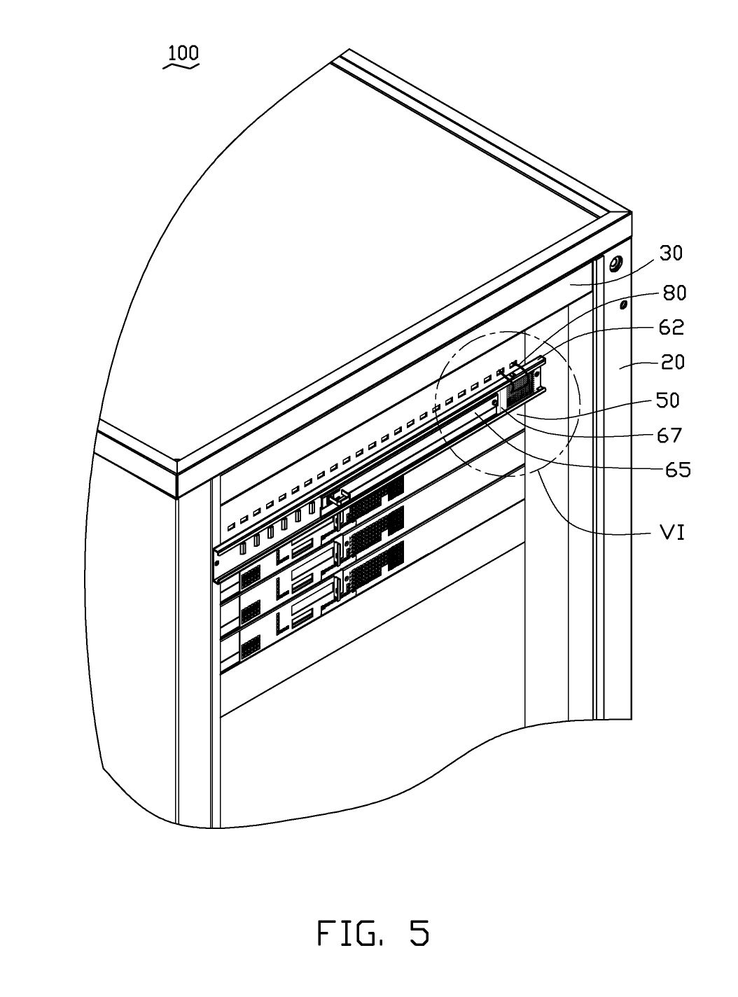

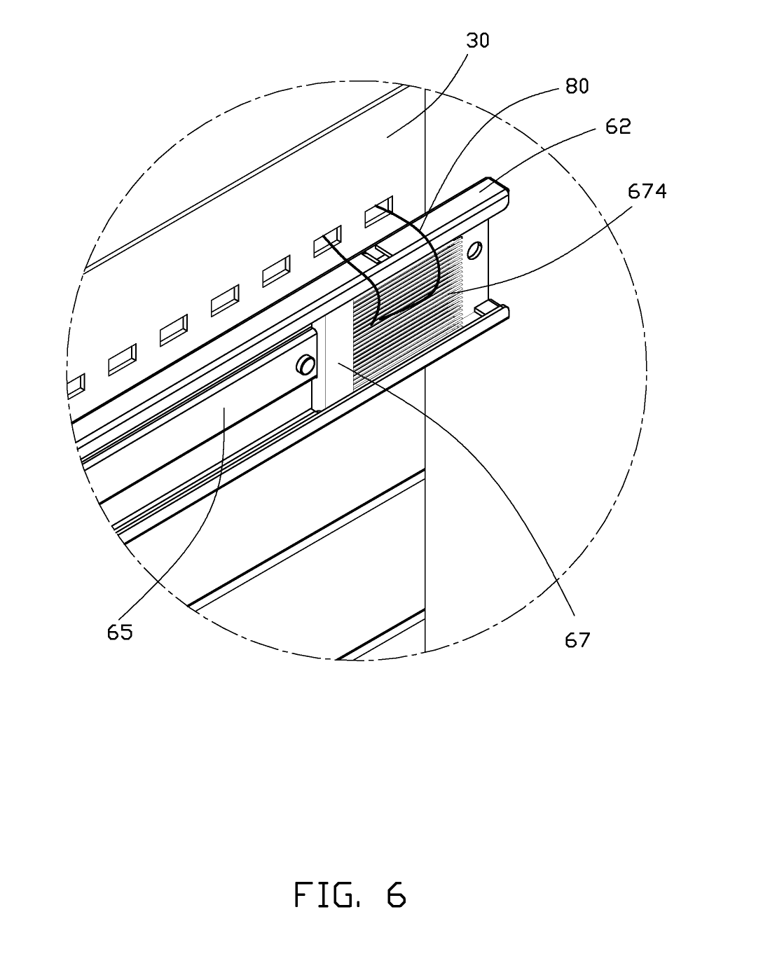

FIGS. 5 and 6 show that in use, the cable management apparatus 60 is placed on a rear end of the rack 20, with the mounting plate 621 and the mounting holes 626 of the frame 62 aligning with the space 70 and the screw holes 22 of the rack 20, respectively. Two screws extend through the mounting holes 626, to be screwed in the screw holes 22. Therefore, the mounting plate 621, the sliding member 65, and the brush 67 cover the space 70 of the rack 20. The operation portion 657 is pulled outward, deforming the extending portion 6582, until the latching portion 6585 is detached from the corresponding latching block 6213. The sliding member 65 is slid away from the stopping pieces 6231, exposing a part of the through hole 6212. First ends of a plurality of cables 80 are connected to the first connectors 32 of the switch 30, and second ends of the cables 80 extend through the through hole 6212 and the space 70 to be connected to the second connectors of the server modules 50. The operation portion 657 is operated, the brush portion 674 is moved to cover the through hole 6212, and the cables 80 are positioned in the brush portion 674.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A cable management apparatus to manage cables, the cable management comprising:
a frame defining a through hole for the cables extending through;
a sliding member slidably installed to the frame; and
an air shield member mounted on an end of the sliding member;
wherein the sliding member is slid to allow the air shield member to cover the through hole, and the cables to extend through the air shield member.

2. The cable management apparatus of claim 1, wherein the air shield member comprises a handle mounted to the sliding member and a brush portion mounted to the handle and opposite to the sliding member, the cables extend through the brush portion.

3. The cable management apparatus of claim 1, wherein the frame comprises a rectangular mounting plate and two flanges extending from two opposite sides of the mounting plate toward the same direction, the mounting plate and the flanges cooperatively bound a receiving space, the sliding member and the air shield member are slidably received in the receiving space, the through hole is defined in a first end of the mounting plate.

4. The cable management apparatus of claim 3, wherein the through hole extends along a sliding direction of the air shield member.

5. The cable management apparatus of claim 3, wherein a stopping piece protrudes from one of the flanges toward the receiving slot and adjacent to the first end of the mounting plate, the air shield member is stopped by the stopping piece.

6. The cable management apparatus of claim 3, wherein the sliding member comprises a rectangular sliding bar and two guiding bars extending out from two opposite sides of the sliding bar, the guiding bars are slidably engaged with inner surfaces of the flanges of the frame.

7. The cable management apparatus of claim 6, wherein an inner side of the sliding bar opposite to the guiding bars defines a guiding slot extending along the sliding direction of the air shield member, a row of latching blocks protrudes from a second end of the mounting plate opposite to the through hole, the latching blocks are received in the guiding slot of the sliding member, a resilient tongue protrudes from the sliding member toward the receiving slot of the frame, the tongue is selectively latched to one of the latching blocks to position the air shield member.

8. The cable management apparatus of claim 7, wherein the sliding bar defines a slot opposite to the air shield member, the tongue extends into the slot from an end wall bounding the slot adjacent to the air shield member.

9. The cable management apparatus of claim 8, wherein the tongue comprises a resilient extending portion extending into the receiving slot from the sliding bar, a guiding portion slantingly extending from a distal end of the extending portion toward the receiving slot and away from the air shield member, and a latching portion extending from a distal end of the guiding portion along a same direction with the extending portion.

10. The cable management apparatus of claim 9, wherein each latching block defines a guiding surface opposite to the through hole, the guiding portion of the tongue is slidably abutted against the guiding surface of one of the latching blocks, deforming the extending portion, until the latching portion moves across the latching block, the extending portion is restored to bias the latching portion to latch with the latching block.

11. The cable management apparatus of claim 7, wherein an operation portion protrudes out from an outer surface of the tongue.

12. A rack-mount server assembly, comprising:
a rack;
a server module received in the rack;
a switch received in the rack and adjacent to the server module;
a cable connected between the switch and the server module; and
a cable management apparatus comprising:
a frame defining a through hole for the cable extending through;
a sliding member slidably installed in the frame; and
an air shield member mounted on an end of the sliding member;
wherein the switch and the server module cooperatively bound a space, the frame is mounted to the rack and aligns with the space, the through hole is communicated with the space, the sliding member is slid to allow the air shield member to cover or uncover the through hole, the cable extends through the air shield member in response to the air shield member covering the through hole.

13. The rack-mount server assembly of claim 12, wherein the air shield member comprises a handle mounted to the sliding member and a brush portion mounted to the handle away from the sliding member, the cable extends through the brush portion.

14. The rack-mount server assembly of claim 12, wherein the frame comprises a rectangular mounting plate aligning with the space and two flanges extending from two opposite sides of the mounting plate toward the same direction, the mounting plate and the flanges cooperatively bound a receiving space, the sliding member and the air shield member are slidably received in the receiving space, the through hole is defined in a first end of the mounting plate.

15. The rack-mount server assembly of claim 14, wherein a stopping piece protrudes from one of the flanges toward the receiving slot and adjacent to the through hole, the air shield member is stopped by the stopping piece.

16. The rack-mount server assembly of claim 14, wherein the sliding member comprises a rectangular sliding bar and two guiding bars extending out from two opposite sides of the sliding bar, the guiding bars are slidably engaged with inner surfaces of the flanges of the frame.

17. The rack-mount server assembly of claim 16, wherein an inner side of the sliding bar opposite to the guiding bars defines a guiding slot extending along the sliding direction of the air shield member, a row of latching blocks protrudes from a second end of the mounting plate opposite to the through hole, the latching blocks are received in the guiding slot of the sliding member, a resilient tongue protrudes from the sliding member toward the receiving slot of the frame, the tongue is detachably latched to one of the latching blocks.

18. The rack-mount server assembly of claim 17, wherein the sliding bar defines a slot opposite to the air shield member, the tongue extends into the slot from an end wall bounding the slot adjacent to the air shield member.

19. The rack-mount server assembly of claim 18, wherein the tongue comprises a resilient extending portion extending into the receiving slot from the sliding bar, a guiding portion slantingly extending from a distal end of the extending portion toward the receiving slot and away from the air shield member, and a latching portion extending from a distal end of the guiding portion along a same direction with the extending portion.

20. The rack-mount server assembly of claim 19, wherein each latching block defines a guiding surface opposite to the through hole, the guiding portion of the tongue is slidably abutted against the guiding surface of one of the latching blocks, deforming the extending portion, until the latching portion moves across the latching block, the extending portion is restored to bias the latching portion to latch with the latching block.
